(19) United States
(12) Patent Application Publication
(10) Pub. No.: US 2011/0100292 A1
(43) Pub. Date: May 5, 2011

(54) METHOD FOR GROWING GaN CRYSTAL

(75) Inventors: Koji Uematsu, Hyogo (JP); Hiroaki Yoshida, Hyogo (JP); Masanori Morishita, Hyogo (JP); Shinsuke Fujiwara, Hyogo (JP)

(73) Assignee: SUMITOMO ELECTRIC INDUSTRIES, LTD., Osaka (JP)

(21) Appl. No.: 13/003,540

(22) PCT Filed: Jul. 14, 2009
(86) PCT No.: PCT/JP2009/062728

§ 371 Date: Jan. 10, 2011

(30) Foreign Application Priority Data
Jul. 16, 2008 (JP) 2008-184825
Sep. 30, 2008 (JP) 2008-252791

(51) Int. Cl. C30B 19/04

(52) U.S. Cl. 117/58; 117/54

(57) ABSTRACT

A method for growing a GaN crystal includes a step of preparing a substrate (10) that includes a main surface (10m) and includes a Gaₓ Al_{y} In_{1-x-y} N seed crystal (10a) including the main surface (10m) and a step of growing a GaN crystal (20) on the main surface (10m) at an atmosphere temperature of 800° C. or more and 1500° C. or less and at an atmosphere pressure of 500 atmospheres or more and less than 2000 atmospheres by bringing a solution (7) provided by dissolving (5) nitrogen in a Ga melt (3) into contact with the main surface (10m) of the substrate (10). The method further includes, after the step of preparing the substrate (10) and before the step of growing the GaN crystal (20), a step of etching the main surface (10m) of the substrate (10). Thus, a method for growing a GaN crystal having a low dislocation density and high crystallinity is provided without adding impurities other than raw materials to the melt and without increasing the size of a crystal growth apparatus.

### TECHNICAL FIELD

The present invention relates to a method for growing a GaN crystal that has a low dislocation density and is preferably used as a substrate for various semiconductor devices such as light emitting devices, electronic devices, and semiconductor sensors.

### BACKGROUND ART

GaN crystals are very useful as a material for forming substrates of various semiconductor devices such as light emitting devices, electronic devices, and semiconductor sensors. Here, to enhance characteristics of various semiconductor devices, GaN crystal substrates having a low dislocation density and high crystallinity are required.

Here, a liquid-phase growth method using a melt containing Ga is regarded as promising because GaN crystals having a low dislocation density can be grown, compared with a vapor-phase growth method such as a hydride vapor phase epitaxy (HVPE) method or a metal organic chemical vapor deposition (MOCVD) method.

For example, Domestic Re-publication of PCT International Publication for Patent Application No. WO99/34037 (hereafter, referred to as Patent Literature 1 (PTL 1)) discloses a method for growing a GaN crystal by dissolving a nitrogen gas in a Ga melt in an atmosphere at a high temperature of 1000 K to 2800 K (preferably, 1600 K to 2800 K) and a high pressure of 2000 atmospheres to 45000 atmospheres (preferably, 10000 atmospheres to 45000 atmospheres).

However, the crystal growth method of PTL 1 requires a pressure of as high as 2000 atmospheres (202.6 MPa) to 45000 atmospheres (4.56 GPa) and, preferably, 10000 atmospheres (1.01 GPa) to 45000 atmospheres (4.56 GPa). To provide such a high pressure, simply supplying a compressed nitrogen gas into a crystal growth vessel is insufficient and an extra pressurizing device is required. In addition, a pressure-tight vessel that can withstand such a high pressure is required. Accordingly, a large-scale apparatus is required, which is problematic.

Then, as a liquid-phase growth method using a melt containing metal Ga, a method in which the pressure of an atmosphere during crystal growth is reduced has been proposed. For example, H. Yamane and four others, “Preparation of GaN Single Crystals Using a Na Flux”, Chemistry of Materials, (1997), Vol. 9, pp. 413-416 (hereafter, referred to as Non Patent Literature 1 (NPL 1)) discloses a method for growing a GaN crystal in which Na is used as a flux. In this method, sodium azide (NaN₃) serving as a flux and metal Ga that are used as raw materials are enclosed in a stainless-steel reaction vessel (vessel internal dimensions: internal diameter=7.5 mm and length=100 mm) in a nitrogen atmosphere; and the reaction vessel is maintained at a temperature of 600° C. to 800° C. for 24 to 100 hours to grow a GaN crystal.

In the crystal growth method of NPL 1, since the atmosphere pressure during the crystal growth is about 100 kgf/cm² at most, a simple crystal growth apparatus can be used compared with the crystal growth method of PTL 1. However, in the crystal growth method of NPL 1, since metal Na is contained in the melt used for the crystal growth, Na is incorporated as an impurity into the GaN crystal being grown, which is problematic.

### Citation List

### Patent Literature

PTL 1: Domestic Re-publication of PCT International Publication for Patent Application No. WO99/34037

### Non Patent Literature

NPL 1: H. Yamane and four others, “Preparation of GaN Single Crystals Using a Na Flux”, Chemistry of Materials, (1997), Vol. 9, pp. 413-416

### SUMMARY OF INVENTION

### Technical Problem

An object of the present invention is to overcome the above-described problems in a liquid-phase growth method using a melt containing Ga and to provide a method for growing a GaN crystal having a low dislocation density and high crystallinity without adding impurities other than raw materials (gallium and nitrogen) to the melt and without increasing the size of a crystal growth apparatus.

### Solution to Problem

The present invention provides a method for growing a GaN crystal including a step of preparing a substrate that includes a main surface and includes a Gaₓ Al_{y} In_{1-x-y} N (0<x, 0≦y, and x+y≦1) seed crystal including the main surface, and a step of growing a GaN crystal on the main surface at an atmosphere temperature of 800° C. or more and 1500° C. or less and at an atmosphere pressure of 500 atmospheres or more and less than 2000 atmospheres by bringing a solution provided by dissolving nitrogen in a Ga melt into contact with the main surface of the substrate.

The method for growing a GaN crystal according to the present invention may further include, after the step of preparing the substrate and before the step of growing the GaN crystal, a step of etching the main surface of the substrate. Here, the step of etching the main surface of the substrate may be performed by bringing the solution provided by dissolving nitrogen in the Ga melt into contact with the main surface of the substrate at an atmosphere temperature of 800° C. or more and 1500° C. or less and at an atmosphere pressure of 1 atmosphere or more and less than 500 atmospheres.

In the method for growing a GaN crystal according to the present invention, the Gaₓ Al_{y} In_{1-x-y} N seed crystal of the substrate may include a main crystal region and a crystal region with an inverted polarity in which a polarity in a [0001] direction is inverted with respect to the main crystal region. In addition, in the substrate, a main surface of the crystal region with the inverted polarity may be recessed at a depth of 10 μm or more with respect to a main surface of the main crystal region.

The method for growing a GaN crystal according to the present invention may be performed such that, in the step of preparing the substrate, a plurality of the substrates are prepared, a plurality of crystal growth vessels each containing one or more of the substrates are prepared, and the plurality of crystal growth vessels are arranged in at least one of a horizontal direction and a vertical direction in a crystal growth chamber.

### Advantageous Effects of Invention

According to the present invention, the above-described problems in a liquid-phase growth method using a Ga melt can be overcome and a method for growing a GaN crystal having a low dislocation density and high crystallinity can be provided without adding impurities other than raw materials (gallium and nitrogen) to the melt and without increasing the size of a crystal growth apparatus.

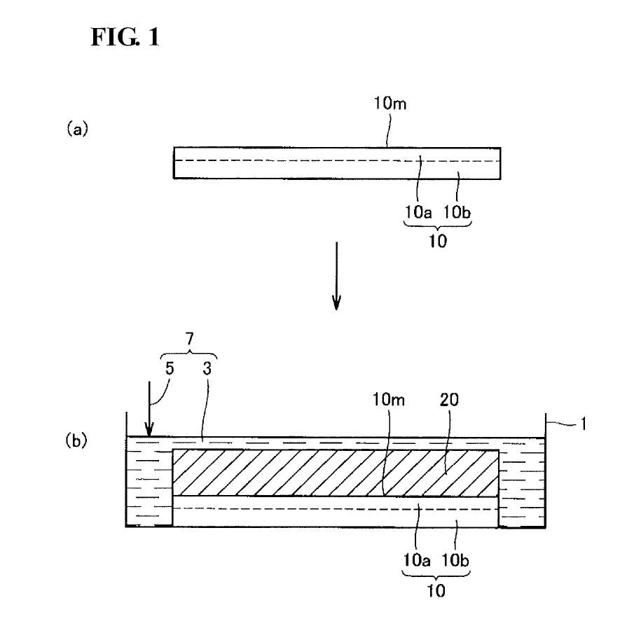

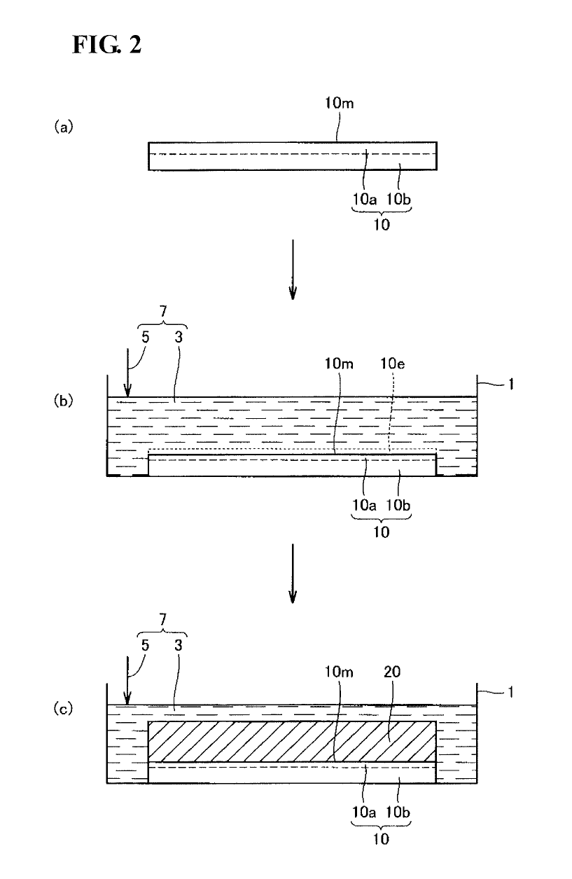

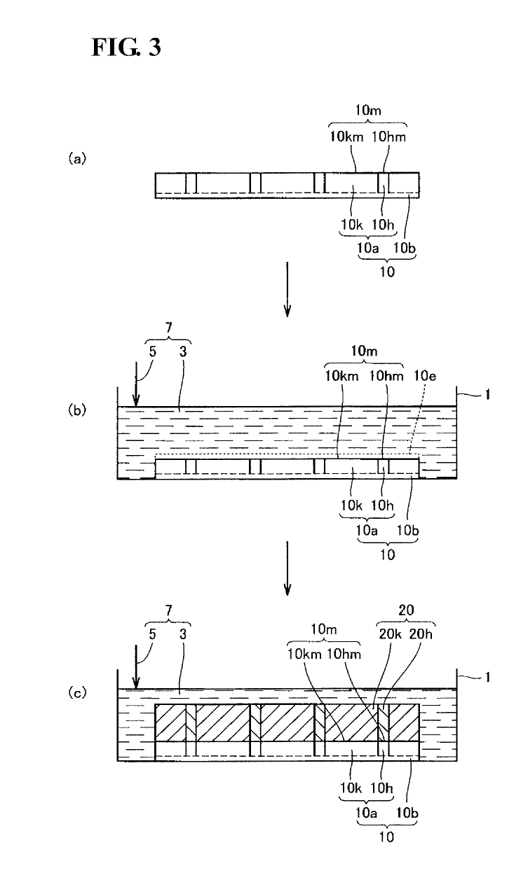

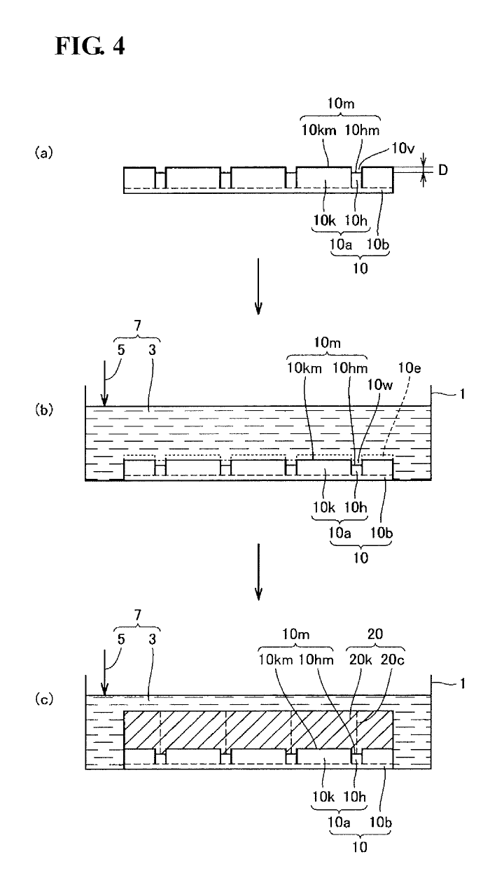

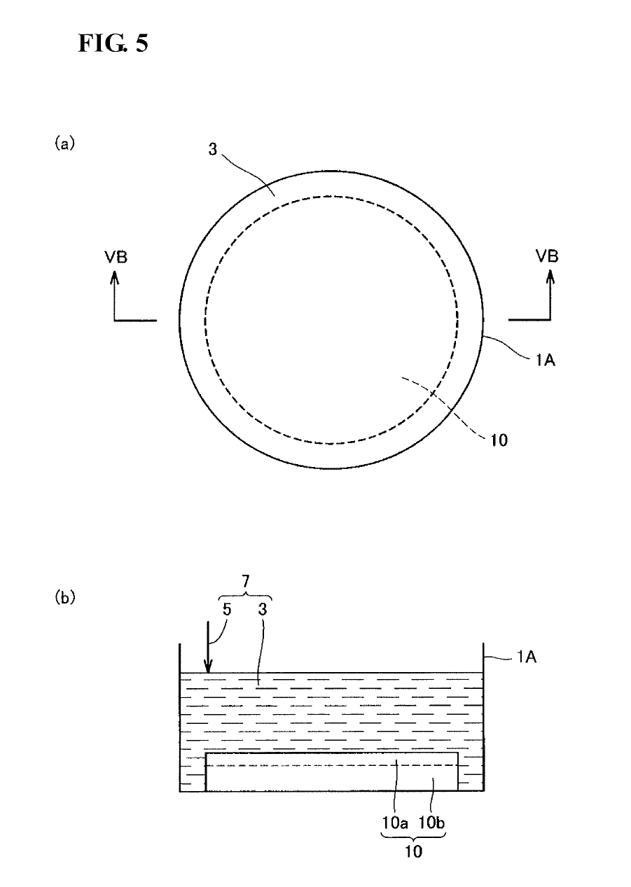

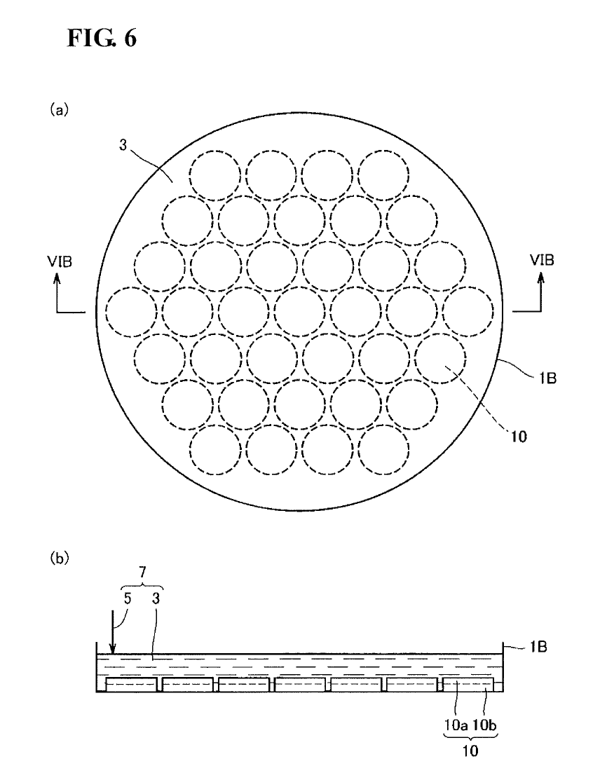

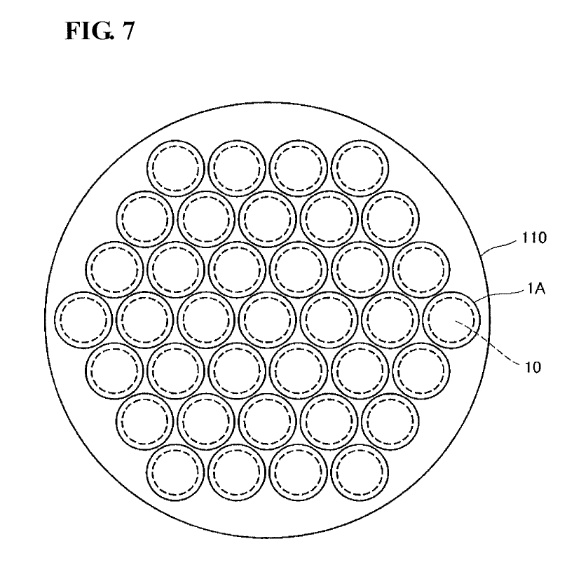

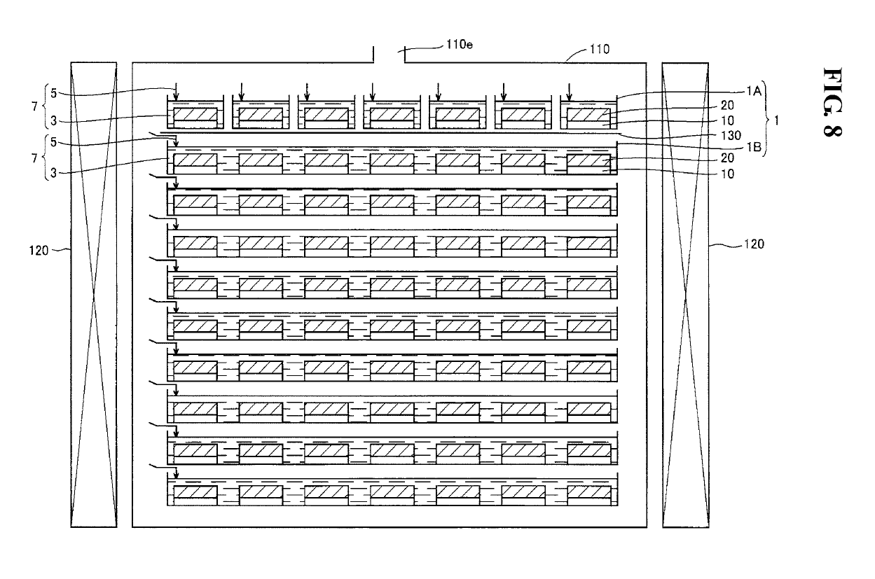

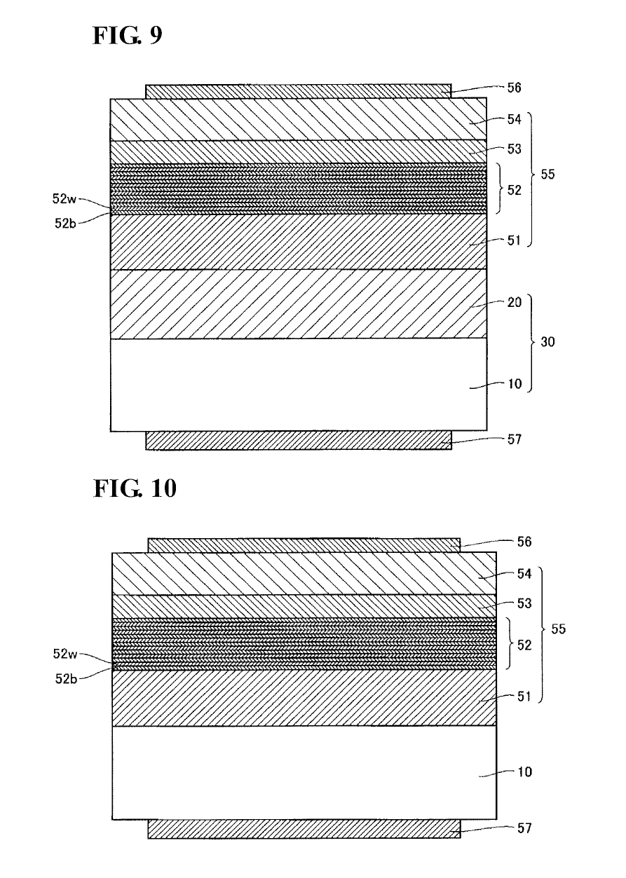

### BRIEF DESCRIPTION OF DRAWINGS

[FIG. 1] FIG. 1 is a schematic sectional view illustrating a method for growing a GaN crystal according to an embodiment of the present invention. Here, (a) illustrates a step of preparing a substrate and (b) illustrates a step of growing a GaN crystal.

[FIG. 2] FIG. 2 is a schematic sectional view illustrating a method for growing a GaN crystal according to another embodiment of the present invention. Here, (a) illustrates a step of preparing a substrate, (b) illustrates a step of etching a surface of the substrate, and (c) illustrates a step of growing a GaN crystal.

[FIG. 3] FIG. 3 is a schematic sectional view illustrating a method for growing a GaN crystal according to still another embodiment of the present invention. Here, (a) illustrates a step of preparing a substrate, (b) illustrates a step of etching a surface of the substrate, and (c) illustrates a step of growing a GaN crystal.

[FIG. 4] FIG. 4 is a schematic sectional view illustrating a method for growing a GaN crystal according to still another embodiment of the present invention. Here, (a) illustrates a step of preparing a substrate, (b) illustrates a step of etching a surface of the substrate, and (c) illustrates a step of growing a GaN crystal.

[FIG. 5] FIG. 5 is a schematic view illustrating an example of a crystal growth vessel containing a substrate used in a method for growing a GaN crystal according to the present invention. Here, (a) illustrates a schematic top view of the crystal growth vessel and (b) illustrates a schematic sectional view taken along VB-VB in (a).

[FIG. 6] FIG. 6 is a schematic view illustrating another example of a crystal growth vessel containing a substrate used in a method for growing a GaN crystal according to the present invention. Here, (a) illustrates a schematic top view of the crystal growth vessel and (b) illustrates a schematic sectional view taken along VIB-VIB in (a).

[FIG. 7] FIG. 7 is a schematic top view illustrating an example of arrangement of crystal growth vessels containing substrates used in a method for growing a GaN crystal according to the present invention.

[FIG. 8] FIG. 8 is a schematic top view illustrating another example of arrangement of crystal growth vessels containing substrates used in a method for growing a GaN crystal according to the present invention.

[FIG. 9] FIG. 9 is a schematic sectional view illustrating a light emitting device fabricated using a GaN crystal growth according to the present invention.

[FIG. 10] FIG. 10 is a schematic sectional view illustrating a typical light emitting device.

### DESCRIPTION OF EMBODIMENTS

### First Embodiment

Referring to FIG. 1, a method for growing a GaN crystal according to an embodiment of the present invention includes a step of preparing a substrate 10 that includes a main surface 10m and includes a Gaₓ Al_{y} In_{1-x-y} N (0<x, 0≦y, and x+y≦1; hereafter, same definition.) seed crystal 10a including the main surface 10m, and a step of growing a GaN crystal 20 on the main surface 10m at an atmosphere temperature of 800° C. or more and 1500° C. or less and at an atmosphere pressure of 500 atmospheres (50.7 MPa) or more and less than 2000 atmospheres (202.6 MPa) by bringing a solution 7 provided by dissolving nitrogen in a Ga melt 3 (dissolution 5 of nitrogen in the Ga melt) into contact with the main surface 10m of the substrate 10.

First, referring to FIG. 1(a), the method for growing a GaN crystal according to the first embodiment includes the step of preparing the substrate 10 that includes the main surface 10m and includes the Gaₓ Al_{y} In_{1-x-y} N seed crystal 10a including the main surface 10m. By preparing such a substrate 10, a large GaN crystal having a low dislocation density and high crystallinity can be readily grown on the main surface 10m of the Gaₓ Al_{y} In_{1-x-y} N seed crystal 10a of the substrate 10.

Here, the substrate 10 including the main surface 10m at least includes the Gaₓ Al_{y} In_{1-x-y} N seed crystal 10a including the main surface 10m. Thus, the substrate 10 may be a template substrate in which the Gaₓ Al_{y} In_{1-x-y} N seed crystal 10a is formed on an undersubstrate 10b or a Gaₓ Al_{y} In_{1-x-y} N seed crystal free-standing substrate in which the whole substrate is formed of the Gaₓ Al_{y} In_{1-x-y} N seed crystal 10a. When the substrate 10 is a template substrate, as the undersubstrate 10b, a sapphire substrate, a SiC substrate, a GaAs substrate, or the like that has small lattice mismatch with the Gaₓ Al_{y} In_{1-x-y} N seed crystal 10a is preferably used. In the substrate 10, a method for forming the Gaₓ Al_{y} In_{1-x-y} N seed crystal 10a on the undersubstrate 10b is not particularly restricted and may be a vapor-phase growth method such as a hydride vapor phase epitaxy (HVPE) method or a metal organic chemical vapor deposition (MOCVD) method or a liquid-phase growth method such as a melt growth method.

In view of growing a GaN crystal having a low dislocation density and high crystallinity, the larger the composition proportion of Ga in the Gaₓ Al_{y} In_{1-x-y} N seed crystal 10a is, the more preferable it is. For example, the composition proportion of Ga is preferably 0.5<x≦1 and preferably 0.75<x≦1.

Then, referring to FIG. 1(b), the method for growing a GaN crystal according to the first embodiment also includes the step of growing the GaN crystal 20 on the main surface 10m at an atmosphere temperature of 800° C. or more and 1500° C. or less and at an atmosphere pressure of 500 atmospheres or more and less than 2000 atmospheres by bringing the solution 7 provided by dissolving nitrogen in the Ga melt 3 (dissolution 5 of nitrogen in the Ga melt) into contact with the main surface 10m of the substrate 10.

The growth of a GaN crystal by a conventional liquid-phase growth method using a Ga melt requires a high temperature of 1000 K (727° C.) to 2800 K (2527° C.) and a high pressure of 2000 atmospheres (202.6 MPa) to 45000 atmospheres (4.56 GPa). In contrast, by bringing the solution 7 provided by dissolving nitrogen in the Ga melt 3 (dissolution 5 of nitrogen in the Ga melt) into contact with the main surface 10m of the Gaₓ Al_{y} In_{1-x-y} N seed crystal 10a of the substrate 10, the growth of a GaN crystal has been made possible even at an atmosphere temperature of 800° C. or more and 1500° C. or less and at an atmosphere pressure of 500 atmospheres (50.7 MPa) or more and less than 2000 atmospheres (202.6 MPa). Here, although the dissolution 5 of nitrogen in the Ga melt 3 is not particularly restricted, in view of ease of controlling the amount of nitrogen dissolved, the dissolution 5 is preferably performed by bringing a nitrogen-containing gas into contact with the Ga melt 3. The atmosphere pressure is provided by the dissolution of a nitrogen-containing gas in the Ga melt 3 (dissolution 5 of nitrogen in the Ga melt).

Ga for forming the melt is not particularly restricted. However, in view of reducing incorporation of impurities into a GaN crystal, Ga having a high purity is preferred: for example, preferably Ga having a purity of 99.99 mass % or more and, more preferably, Ga having a purity of 99.9999 mass % or more. The nitrogen-containing gas is not particularly restricted and nitrogen (N₂) gas, ammonia (NH₃) gas, or the like may be used. However, in view of reducing entry of impurities into a GaN crystal, a nitrogen gas having a high purity is preferred: for example, preferably a nitrogen gas having a purity of 99.99 mass % or more and, more preferably, a nitrogen gas having a purity of 99.9999 mass % or more.

When the atmosphere temperature is less than 800° C., crystal growth proceeds slowly and a very long time is required for providing a crystal having a practical size. When the atmosphere temperature is more than 1500° C., crystal decomposition proceeds rather than crystal growth and hence a crystal having a practical size is not provided. When the atmosphere pressure is less than 500 atmospheres, crystal growth proceeds slowly and a very long time is required for providing a crystal having a practical size. When the atmosphere pressure is 2000 atmospheres or more, a crystal growth apparatus requires an extra pressurizing mechanism, which increases the cost of the crystal growth.

### Second Embodiment

Referring to FIG. 2, a method for growing a GaN crystal according to another embodiment of the present invention further includes, after the step of preparing a substrate (FIG. 2(a)) and before the step of growing a GaN crystal (FIG. 2(c)) in the first embodiment, a step of etching the main surface 10m of the substrate 10 (FIG. 2(b)).

By etching the main surface 10m of the substrate 10, for example, a work-affected layer formed in the substrate in the preparation of the substrate or a surface oxidized layer formed after the preparation of the substrate is removed. Accordingly, a GaN crystal having an extremely low dislocation density and extremely high crystallinity can be grown on the main surface of the substrate.

Here, the technique of etching the main surface 10m of the substrate 10 is not particularly restricted. However, a technique with which direct transition from the etching to the crystal growth step can be achieved without exposing the resultant surface to the air, for example, a technique of etching with the solution 7 provided by dissolving nitrogen in the Ga melt 3 (dissolution 5 of nitrogen in the Ga melt) is preferred. This is because, when the main surface 10m of the substrate 10 is etched in advance, in the preparation stage for the growth using the Ga solution, a surface oxidized layer is necessarily formed on the main surface 10m or stains or the like adhere to the main surface 10m, and crystal growth on such a main surface results in the formation of defects.

First, referring to FIG. 2(a), the method for growing a GaN crystal according to the second embodiment includes the step of preparing the substrate 10 including the main surface 10m and includes the Gaₓ Al_{y} In_{1-x-y} N (0<x, 0≦y, and x+y≦1) seed crystal 10a including the main surface 10m. This step is the same as that described in the first embodiment.

Then, referring to FIG. 2(b), the method for growing a GaN crystal according to the second embodiment includes the step of etching the main surface 10m of the substrate 10. A surface layer 10e of the substrate 10 to be etched includes, for example, a work-affected layer formed in the substrate in the preparation of the substrate, a surface oxidized layer formed after the preparation of the substrate, or stains adhering to the substrate. As a result of the etching, the main surface 10m from which the surface layer 10e has been removed is provided.

Here, the step of etching the main surface 10m of the substrate 10 is not particularly restricted. However, this step is preferably performed by bringing the solution 7 provided by dissolving nitrogen in the Ga melt 3 (dissolution 5 of nitrogen in the Ga melt) into contact with the main surface 10m of the substrate 10 at an atmosphere temperature of 800° C. or more and 1500° C. or less and at an atmosphere pressure of 1 atmosphere (0.1 MPa) or more and less than 500 atmospheres (50.7 MPa). Here, although the dissolution 5 of nitrogen in the Ga melt 3 is not particularly restricted, in view of ease of controlling the amount of nitrogen dissolved, the dissolution 5 is preferably performed by bringing a nitrogen-containing gas into contact with the Ga melt 3. The atmosphere pressure is provided by the dissolution of a nitrogen-containing gas in the Ga melt 3 (dissolution 5 of nitrogen in the Ga melt). Here, when the atmosphere temperature is less than 800° C., the etching rate for the main surface (that is, the rate at which the main surface is etched. Hereafter, same meaning.) is low and the etching step requires a long time. When the atmosphere temperature is more than 1500° C., the etching rate for the main surface is too high and it is difficult to control the etching step. When the atmosphere pressure is less than 1 atmosphere, the etching rate for the main surface is too high and it is difficult to control the etching step. When the atmosphere pressure is more than 500 atmospheres, the etching rate for the main surface is low and the etching step requires a long time.

Then, referring to FIG. 2(c), the method for growing a GaN crystal according to the second embodiment includes the step of growing the GaN crystal 20 on the main surface 10m at an atmosphere temperature of 800° C. or more and 1500° C. or less and at an atmosphere pressure of 500 atmospheres or more and less than 2000 atmospheres by bringing the solution 7 provided by dissolving nitrogen in the Ga melt 3 (dissolution 5 of nitrogen in the Ga melt) into contact with the main surface 10m of the substrate 10. This step is the same as that described in the first embodiment. However, in the second embodiment, since the GaN crystal is grown on the main surface 10m of the substrate having been etched, a GaN crystal having a low dislocation density and high crystallinity can be provided, compared with a GaN crystal provided in the first embodiment.

### Third Embodiment

Referring to FIG. 3, as for a method for growing a GaN crystal according to still another embodiment of the present invention, in the first embodiment or the second embodiment, the Gaₓ Al_{y} In_{1-x-y} N seed crystal 10a of the substrate 10 includes main crystal regions 10k and crystal regions 10h with an inverted polarity in which the polarity in the [0001] direction is inverted with respect to the main crystal regions 10k. Compared with the substrate in the first embodiment or the second embodiment, this substrate 10 has a low dislocation density in the main crystal regions and hence the GaN crystal 20 having a low dislocation density and high crystallinity can be grown on main surfaces 10km of the main crystal regions 10k of the substrate 10.

First, referring to FIG. 3(a), the method for growing a GaN crystal according to the third embodiment includes the step of preparing the substrate 10 including the main surface 10m and includes the Gaₓ Al_{y} In_{1-x-y} N (0<x, 0≦y, and x+y≦1) seed crystal 10a including the main surface 10m. In the substrate 10 prepared in the third embodiment, the Gaₓ Al_{y} In_{1-x-y} N seed crystal 10a includes the main crystal regions 10k and the crystal regions 10h with an inverted polarity in which the polarity in the [0001] direction is inverted with respect to the main crystal regions 10k. In the Gaₓ Al_{y} In_{1-x-y} N seed crystal 10a of the substrate 10, the crystal regions 10h with an inverted polarity are not particularly restricted; however, for example, the crystal regions 10h are in the form of stripes or dots when viewed from the main surface 10m. When viewed from the main surface 10m, the crystal regions 10h with an inverted polarity have a width of, for example, 5 μm to 200 μm; and the crystal regions 10h with an inverted polarity have a pitch of, for example, 50 μm to 2000 μm.

A method for growing the Gaₓ Al_{y} In_{1-x-y} N seed crystal 10a of the substrate 10 prepared in the third embodiment is not particularly restricted. However, a facet growth method may be employed in which crystal growth is performed while facets are grown and maintained as described in Japanese Unexamined Patent Application Publication No. 2003-183100. The resultant Gaₓ Al_{y} In_{1-x-y} N seed crystal 10a includes the main crystal regions 10k having a low dislocation density, and the crystal regions 10h with an inverted polarity in which the polarity in the [0001] direction is inverted with respect to the main crystal regions 10k and the dislocation density is higher than that of the main crystal regions 10k.

Then, referring to FIG. 3(b), the method for growing a GaN crystal according to the third embodiment includes the step of etching the main surface 10m of the substrate 10. The step of etching the main surface 10m of the substrate 10 is performed as in the second embodiment. In the third embodiment, in the etching step, in the Gaₓ Al_{y} In_{1-x-y} N seed crystal 10a, main surfaces 10hm of the crystal regions 10h with an inverted polarity and the main surfaces 10km of the main crystal regions 10k are etched substantially at the same rate.

Then, referring to FIG. 3(c), the method for growing a GaN crystal according to the third embodiment includes the step of growing the GaN crystal 20 on the main surface 10m at an atmosphere temperature of 800° C. or more and 1500° C. or less and at an atmosphere pressure of 500 atmospheres or more and less than 2000 atmospheres by bringing the solution 7 provided by dissolving nitrogen in the Ga melt 3 (dissolution 5 of nitrogen in the Ga melt) into contact with the main surface 10m of the substrate 10. As described in the second embodiment, in this step, since the GaN crystal 20 is grown on the main surface 10m of the substrate having been etched, a GaN crystal having a low dislocation density and high crystallinity can be provided, compared with a GaN crystal provided in the first embodiment.

Furthermore, the Gaₓ Al_{y} In_{1-x-y} N seed crystal 10a of the substrate 10 in the third embodiment includes the main crystal regions 10k having a low dislocation density, and the crystal regions 10h with an inverted polarity in which the polarity in the [0001] direction is inverted and the dislocation density is high, compared with the main crystal regions 10k. Accordingly, when the GaN crystal 20 is grown on the main surface 10m of the Gaₓ Al_{y} In_{1-x-y} N seed crystal 10a of the substrate 10, main crystal regions 20k of a GaN crystal are grown on the main crystal regions 10k of the substrate 10 so as to inherit the polarity and the low dislocation density of the main crystal regions 10k, and crystal regions 201 with an inverted polarity in which the polarity in the [0001] direction is inverted and the dislocation density is high compared with the main crystal regions 20k are grown on the crystal regions 10h with an inverted polarity of the substrate 10 so as to inherit the polarity and the high dislocation density of the crystal regions 10h.

Thus, in the method for growing a GaN crystal according to the third embodiment, the main crystal regions 20k having a low dislocation density in the GaN crystal 20 can be grown on the main surfaces 10km of the main crystal regions 10k of the substrate 10.

### Fourth Embodiment

Referring to FIG. 4, in a method for growing a GaN crystal according to still another embodiment of the present invention, in the first embodiment or the second embodiment, the Gaₓ Al_{y} In_{1-x-y} N seed crystal 10a of the substrate 10 includes main crystal regions 10k and crystal regions 10h with an inverted polarity in which the polarity in the [0001] direction is inverted with respect to the main crystal regions 10k. The main surfaces 10hm of the crystal regions 10h with an inverted polarity are recessed at a depth D of 10 μm or more with respect to the main surfaces 10km of the main crystal regions 10k.

Compared with the substrate prepared in the third embodiment, in this substrate 10, the main surfaces 10hm of the crystal regions 10h with an inverted polarity are recessed at the depth D of 10 μm or more with respect to the main surfaces 10km of the main crystal regions 10k. Accordingly, crystal regions of a GaN crystal with an inverted polarity are not grown on the main surfaces 10hm of the crystal regions 10h with an inverted polarity and the GaN crystal 20 is provided in which the main crystal regions 20k grown on the main surfaces 10km of the main crystal regions 10k are integrated by being bonded together in bonding crystal regions 20c. The GaN crystal 20 inherits the polarity of the main crystal regions 10k of the Gaₓ Al_{y} In_{1-x-y} N seed crystal 10a of the substrate 10 and has a low dislocation density and high crystallinity except in the bonding crystal regions 20c.

First, referring to FIG. 4(a), the method for growing a GaN crystal according to the fourth embodiment includes the step of preparing the substrate 10 including the main surface 10m and includes the Gaₓ Al_{y} In_{1-x-y} N (0<x, 0≦y, and x+y≦1) seed crystal 10a including the main surface 10m. In the substrate 10 prepared in the fourth embodiment, the Gaₓ Al_{y} In_{1-x-y} N seed crystal 10a includes the main crystal regions 10k and the crystal regions 10h with an inverted polarity in which the polarity in the [0001] direction is inverted with respect to the main crystal regions 10k. In terms of these respects, the substrate 10 prepared in the fourth embodiment is the same as the substrate prepared in the third embodiment.

Furthermore, in the substrate 10 prepared in the fourth embodiment, the main surfaces 10hm of the crystal regions 10h with an inverted polarity are recessed at the depth D of 10 μm or more with respect to the main surfaces 10km of the main crystal regions 10k. In terms of this respect, this substrate 10 is different from the substrate prepared in the third embodiment. Here, the depth D of pits 10v (specifically, the pits 10v to be etched) in the main surfaces 10hm of the crystal regions 10h with an inverted polarity with respect to the main surfaces 10km of the main crystal regions 10k needs to be 10 μm or more, preferably 15 μm or more, in view of not losing pits 10w (specifically, the pits 10w having been etched) in the main surfaces 10hm of the crystal regions 10h with an inverted polarity after the subsequent step of etching the main surface 10m. This is because, depending on the technique and conditions of the etching, there are cases where the etching rate for the main surfaces 10km of the main crystal regions 10k is higher than the etching rate for the main surfaces 10hm of the crystal regions 10h with an inverted polarity.

As for the substrate 10 prepared in the fourth embodiment, for example, there are a technique in which the main surface 10m of the substrate 10 prepared in the third embodiment is subjected to dry etching with a chlorine-containing gas (for example, HCl gas, Cl₂ gas, or the like) or wet etching with a strong acid such as hot phosphoric acid or a strong base such as molten KOH or molten NaOH. In such etching technique and conditions, since the etching rate for the main surfaces 10hm of the crystal regions 10h with an inverted polarity (the rate at which the main surfaces are etched) is higher than the etching rate for the main surfaces 10hm of the main crystal regions 10k, the main surfaces 10hm of the crystal regions 10h with an inverted polarity can be recessed with respect to the main surfaces 10km of the main crystal regions 10k.

Then, referring to FIG. 4(b), the method for growing a GaN crystal according to the fourth embodiment includes the step of etching the main surface 10m of the substrate 10. The step of etching the main surface 10m of the substrate 10 is performed as in the second embodiment. In the fourth embodiment, in the etching step, in the Gaₓ Al_{y} In_{1-x-y} N seed crystal 10a, the main surfaces 10hm of the crystal regions 10h with an inverted polarity and the main surfaces 10km of the main crystal regions 10k are etched substantially at the same rate. Accordingly, in the substrate 10 having been etched, the main surfaces 10hm of the crystal regions 10h with an inverted polarity remain recessed with respect to the main surfaces 10km of the main crystal regions 10k.

Then, referring to FIG. 4(c), the method for growing a GaN crystal according to the fourth embodiment includes the step of growing the GaN crystal 20 on the main surface 10m at an atmosphere temperature of 800° C. or more and 1500° C. or less and at an atmosphere pressure of 500 atmospheres or more and less than 2000 atmospheres by bringing the solution 7 provided by dissolving nitrogen in the Ga melt 3 (dissolution 5 of nitrogen in the Ga melt) into contact with the main surface 10m of the substrate 10. As described in the second embodiment, in this step, since the GaN crystal is grown on the main surface 10m of the substrate having been etched, a GaN crystal having a low dislocation density and high crystallinity can be provided, compared with a GaN crystal provided in the first embodiment.

Furthermore, the Gaₓ Al_{y} In_{1-x-y} N seed crystal 10a of the substrate 10 in the fourth embodiment includes the main crystal regions 10k having a low dislocation density, and the crystal regions 10h with an inverted polarity in which the polarity in the [0001] direction is inverted and the dislocation density is high compared with the main crystal regions 10k. The main surfaces 10hm of the crystal regions 10h with an inverted polarity are recessed with respect to the main surfaces 10km of the main crystal regions 10k. Accordingly, when the GaN crystal 20 is grown on the irregularly shaped main surface 10m of the Gaₓ Al_{y} In_{1-x-y} N seed crystal 10a of the substrate 10, not crystal regions of a GaN crystal with an inverted polarity but the main crystal regions 20k grown on the main surfaces 10km of the main crystal regions 10k are grown on the main surfaces 10hm of the crystal regions 10h with an inverted polarity. The GaN crystal 20 is formed in which the plurality of the main crystal regions 20k are integrated by being bonded together at the one or more bonding crystal regions 20c. The resultant GaN crystal 20 inherits the polarity of the main crystal regions 10k of the Gaₓ Al_{y} In_{1-x-y} N seed crystal 10a of the substrate 10 and has a low dislocation density and high crystallinity except in the bonding crystal regions 20c.

### Fifth Embodiment

Referring to FIGS. 1 to 8, in a method for growing a GaN crystal according to still another embodiment of the present invention, in the step of preparing a substrate in the first to fourth embodiments, a plurality of the substrates 10 are prepared, a plurality of crystal growth vessels 1, 1A, and 1B each containing one or more of the substrates 10 are prepared, and the plurality of crystal growth vessels 1, 1A, and 1B are arranged in at least one of the horizontal direction and the vertical direction in a crystal growth chamber 110.

According to the fifth embodiment, referring to FIG. 8, by growing the GaN crystal 20 on each substrate 10 of the plurality of substrates 10, the plurality of GaN crystals 20 can be simultaneously grown and large GaN crystals having a low dislocation density and high crystallinity can be efficiently grown in large quantity. By simultaneously etching the main surfaces 10m of the plurality of substrates 10 and growing the GaN crystal 20 on each substrate 10 of the plurality of etched substrates 10, the plurality of GaN crystals 20 can be simultaneously grown and large GaN crystals having an extremely low dislocation density and extremely high crystallinity can be efficiently grown in large quantity.

Referring to FIGS. 5 and 6, the crystal growth vessels 1, 1A, and 1B used in the fifth embodiment are not particularly restricted unless the crystal growth vessels adversely affect the growth of GaN crystals. For example, crucibles composed of carbon (C), pyrolitic boron nitride (pBN), or alumina (Al₂O₃) may be used. The crystal growth vessels 1A and 1B each contain at least one or more of the substrates 10. Thus, the crystal growth vessel 1A containing the single substrate 10 in FIG. 5 may be employed and the crystal growth vessel 1B containing the plurality of substrates 10 in FIG. 6 may be employed.

Here, in FIG. 6, the arrangement of the plurality of substrates 10 contained in the crystal growth vessel 1B is not particularly restricted. However, in view of arranging the substrates 10 as many as possible within the predetermined region, the plurality of substrates 10 are preferably arranged in a direction parallel to the main surfaces 10m of the substrates 10. In view of such a respect, more preferably, the plurality of substrates 10 are arranged on a surface parallel to the main surfaces 10m of the substrates 10 so as to be close-packed and, still more preferably, arranged so as to be closest-packed. When the plurality of substrates are in the form of discs having the same radius, as illustrated in FIG. 6, the substrates 10 are preferably two-dimensionally arranged so as to be hexagonal close-packed.

Here, as described in the first embodiment or the second embodiment, such a substrate 10 including the main surface 10m at least includes the Gaₓ Al_{y} In_{1-x-y} N seed crystal 10a including the main surface 10m. Thus, the substrate 10 may be a template substrate in which the Gaₓ Al_{y} In_{1-x-y} N seed crystal 10a is formed on the undersubstrate 10b or a Gaₓ Al_{y} In_{1-x-y} N seed crystal free-standing substrate in which the whole substrate is formed of the Gaₓ Al_{y} In_{1-x-y} N seed crystal 10a. As described in the third embodiment, the Gaₓ Al_{y} In_{1-x-y} N seed crystal 10a of such a substrate 10 may include the main crystal regions 10k having a low dislocation density, and the crystal regions 10h with an inverted polarity in which the polarity in the [0001] direction is inverted and the dislocation density is high compared with the main crystal regions 10k. As described in the fourth embodiment, the Gaₓ Al_{y} In_{1-x-y} N seed crystal 10a of such a substrate 10 may include the main crystal regions 10k and the crystal regions 10h with an inverted polarity in which the polarity in the [0001] direction is inverted with respect to the main crystal regions 10k; and the main surfaces 10hm of the crystal regions 10h with an inverted polarity may be recessed at the depth D of 10 μm or more with respect to the main surfaces 10km of the main crystal regions 10k.

Referring to FIGS. 7 and 8, in the fifth embodiment, the crystal growth vessels 1, 1A, and 1B each containing one or more substrates are arranged in at least one of the horizontal direction and the vertical direction in the crystal growth chamber 110. As illustrated in FIG. 7 or the uppermost level in FIG. 8, the crystal growth vessels 1, 1A, and 1B may be arranged in the horizontal direction. As illustrated in levels other than the uppermost level in FIG. 8, the crystal growth vessels 1, 1A, and 1B may be arranged in the vertical direction.

The arrangement of the crystal growth vessels 1A and 1B in the horizontal direction is not particularly restricted. However, in view of arranging the crystal growth vessels as many as possible within the predetermined region, the crystal growth vessels 1A and 1B are preferably arranged, on a horizontal surface, so as to be close-packed and, more preferably, arranged so as to be closest-packed. When the plurality of crystal growth vessels are cylindrical vessels having the same radius, as illustrated in FIG. 7, the crystal growth vessels are preferably two-dimensionally arranged so as to be hexagonal close-packed. The crystal growth vessels 1 are at least arranged such that a nitrogen-containing gas is supplied into the crystal growth vessels 1. The arrangement of the crystal growth vessels 1A and 1B in the vertical direction is not particularly restricted. However, in view of arranging the crystal growth vessels as many as possible within the predetermined region, the crystal growth vessels 1A and 1B are preferably arranged in the vertical direction so as to be close-packed.

In the crystal growth chamber 110, a gas supply port 110e through which a nitrogen-containing gas is supplied into the chamber is provided. Heaters 120 for heating the interior of the crystal growth chamber 110 are provided outside the crystal growth chamber 110.

### EXAMPLES

### Example 1

### 1. Preparation of Substrate

Referring to FIG. 1(a), as the substrate 10, a GaN template substrate was prepared in which a GaN seed crystal (Gaₓ Al_{y} In_{1-x-y} N seed crystal 10a) having a thickness of 3 μm was grown by a MOCVD method on a (0001) main surface of a sapphire substrate (undersubstrate 10b) having a diameter of 2 inches (5.08 cm). The dislocation density of the GaN seed crystal of the GaN template substrate was measured by a cathodoluminescence (CL) method and was found to be 1×10⁹ cm⁻².

### 2. Growth of GaN Crystal

Referring to FIG. 1(b), the GaN template substrate (substrate 10) and 85 g of metal Ga having a purity of 99.9999 mass % were placed in a carbon crucible (crystal growth vessel 1) having an inner diameter of 6 cm and a height of 5 cm disposed in a crystal growth chamber (not shown).

Then, a nitrogen gas having a purity of 99.999 mass % was supplied into the crystal growth chamber. The crucible (crystal growth vessel 1) was maintained at room temperature (25° C.) and pressurized from the atmospheric pressure to 1950 atmospheres (197.5 MPa) in 2 hours, and then maintained at 1950 atmospheres and heated from room temperature to 1100° C. in 3 hours. At this time, the metal Ga placed in the crucible was molten into the Ga melt 3 and the solution 7 provided by the dissolution 5 of nitrogen in the Ga melt 3 was in contact with the main surface 10m of the substrate 10. Then, the crucible was maintained in the nitrogen atmosphere at 1950 atmospheres and at 1100° C. for 10 hours.

The GaN crystal 20 having a thickness of 5 μm was grown on the main surface 10m of the GaN template substrate (substrate 10). Here, the thickness of the GaN crystal was measured by observing a section of the crystal grown on the substrate in the crystal growth direction with a scanning electron microscope (SEM). The full width at a half maximum of the (0002) X-ray diffraction peak of the GaN crystal was 780 arcsec. The dislocation density of the GaN crystal was measured by the CL method and was found to be 2×10⁸ cm⁻², which was lower than the dislocation density of the GaN seed crystal of the substrate.

### Example 2

### 1. Preparation of Substrate

Referring to FIG. 2(a), a GaN template substrate (substrate 10) that was the same as in EXAMPLE 1 was prepared.

### 2. Etching of Main Surface of Substrate

Referring to FIG. 2(b), the GaN template substrate (substrate 10) and 85 g of metal Ga having a purity of 99.9999 mass % were placed in a carbon crucible (crystal growth vessel 1) having an inner diameter of 6 cm and a height of 5 cm disposed in a crystal growth chamber (not shown).

Then, a nitrogen gas having a purity of 99.999 mass % was supplied into the crystal growth chamber. The crucible (crystal growth vessel 1) was maintained at 30 atmospheres (3.04 MPa) and heated from room temperature (25° C.) to 1100° C. over 3 hours. At this time, the metal Ga placed in the crucible was molten into the Ga melt 3 and the solution 7 provided by the dissolution 5 of nitrogen in the Ga melt 3 was in contact with the main surface 10m of the substrate 10. However, under such a condition, since the amount of nitrogen dissolved in the Ga melt was small, a GaN crystal was not grown and the main surface 10m of the GaN seed crystal of the GaN template substrate was etched.

### 3. Growth of GaN Crystal

Then, referring to FIG. 2(b), a nitrogen gas having a purity of 99.999 mass % was supplied into the crystal growth chamber (not shown). The crucible (crystal growth vessel 1) was maintained at 1100° C. and pressurized from 30 atmospheres (3.04 MPa) to 1950 atmospheres (197.5 MPa) in 2 hours. Then, the crucible was maintained in the nitrogen atmosphere at 1950 atmospheres and at 1100° C. for 10 hours.

At this time, the amount of nitrogen dissolved in the Ga melt that was in contact with the main surface 10m of the substrate became large and a GaN crystal was grown. The GaN crystal had a thickness of 5 μm. The full width at a half maximum of the (0002) X-ray diffraction peak of the GaN crystal was 360 arcsec and the GaN crystal had high crystallinity. The dislocation density of the GaN crystal was 7×10⁶ cm⁻², which was lower than the dislocation density of the GaN seed crystal of the substrate and the GaN crystal of EXAMPLE 1.

In EXAMPLE 2, compared with EXAMPLE 1, the full width at a half maximum of the X-ray diffraction peak and the dislocation density were low, that is, the dislocation density was low and the crystallinity was high. This is probably because, as a result of the etching of the main surface of the substrate, a work-affected layer and/or a surface oxidized layer in the main surface of the substrate and/or stains adhering to the main surface of the substrate were removed and good crystal growth was performed.

### Example 3

### 1. Preparation of Substrate

Referring to FIG. 3(a), as the substrate 10, a GaN free-standing substrate that had a diameter of 2 inches (5.08 cm) and was grown by a facet growth method described in Japanese Unexamined Patent Application Publication No. 2003-183100 was prepared. This GaN free-standing substrate included the main crystal regions 10k and the crystal regions 10h with an inverted polarity in which the polarity in the [0001] direction was inverted with respect to the main crystal regions. The dislocation density of the main crystal regions 10k was 1×10⁵ cm⁻². The dislocation density of the crystal regions 10h with an inverted polarity was 5×10⁷ cm⁻².

### 2. Etching of Main Surface of Substrate

Referring to FIG. 3(b), the main surface 10m of the GaN free-standing substrate was etched as in EXAMPLE 2.

### 3. Growth of GaN Crystal

Referring to FIG. 3(c), the GaN crystal 20 was grown on the main surface 10m of the GaN free-standing substrate as in EXAMPLE 2. The GaN crystal had a thickness of 5 μm. The full width at a half maximum of the (0002) X-ray diffraction peak of the GaN crystal was 100 arcsec and the GaN crystal had very high crystallinity. The dislocation density of the main crystal regions 20k (the crystal regions grown on the main surfaces 10km of the main crystal regions 10k of the substrate 10) of the GaN crystal 20 was 1×10⁵ cm⁻², which was substantially equal to the dislocation density of the main crystal regions 10k of the substrate 10. The dislocation density of the crystal regions 20h with an inverted polarity (the crystal regions grown on the main surfaces 10hm of the crystal regions 10h with an inverted polarity of the substrate 10) of the GaN crystal 20 was 5×10⁷ cm⁻², which was equivalent to the dislocation density of the crystal regions 10h with an inverted polarity of the substrate 10. When a 1 N aqueous solution of KOH was brought into contact with the main surface of the GaN crystal 20, the main surfaces of the crystal regions 20h with an inverted polarity of the GaN crystal 20 were etched.

### Example 4

### 1. Preparation of Substrate

Referring to FIG. 4(a), as the substrate 10, a GaN free-standing substrate that had a diameter of 2 inches (5.08 cm) and was grown by a facet growth method described in Japanese Unexamined Patent Application Publication No. 2003-183100 was prepared. This GaN free-standing substrate included the main crystal regions 10k and the crystal regions 10h with an inverted polarity in which the polarity in the [0001] direction was inverted with respect to the main crystal regions. The main surfaces 10hm of the crystal regions 10h with an inverted polarity were recessed at the depth D of 10 μm with respect to the main surfaces 10km of the main crystal regions 10k. These pits were formed by holding the GaN free-standing substrate for about 2 hours in a nitrogen gas atmosphere containing 25 vol % hydrogen chloride gas while the main surface 10m of the GaN free-standing substrate was heated at 800° C. The dislocation density of the main crystal regions 10k was 1×10⁵ cm⁻². The dislocation density of the crystal regions 10h with an inverted polarity was 5×10⁷ cm⁻².

### 2. Etching of Main Surface of Substrate

Referring to FIG. 4(b), the main surface 10m of the GaN free-standing substrate was etched as in EXAMPLE 2.

### 3. Growth of GaN Crystal

Referring to FIG. 4(c), the GaN crystal 20 was grown on the main surface 10m of the GaN free-standing substrate as in EXAMPLE 2. The GaN crystal had a thickness of 5 μm. The full width at a half maximum of the (0002) X-ray diffraction peak of the GaN crystal was 100 arcsec and the GaN crystal had very high crystallinity. The dislocation density of the main crystal regions 20k (the crystal regions grown on the main surfaces 10km of the main crystal regions 10k of the substrate 10) of the GaN crystal 20 was 1×10⁵ cm⁻², which was substantially equal to the dislocation density of the main crystal regions 10k of the substrate 10. The dislocation density of the bonding crystal regions 20c (positioned on the main surfaces 10hm of the crystal regions 10h with an inverted polarity of the substrate 10) in which the plurality of main crystal regions 20k of the GaN crystal 20 were bonded together was 2×10⁶ cm −², which was larger than the dislocation density of the main crystal regions 20k of the GaN crystal 20 but was smaller than the dislocation density of the crystal regions 10h with an inverted polarity of the substrate 10. When a 1 N aqueous solution of KOH was brought into contact with the main surface of the GaN crystal 20, the main surface of the GaN crystal 20 was not etched at all. Thus, no crystal region with an inverted polarity was formed in the GaN crystal of EXAMPLE 4.

### Example 5

### 1. Preparation of Substrate

Referring to FIG. 2(a), as the substrate 10, a GaN free-standing substrate having a (1-100) main surface and a diameter of 2 inches (5.08 cm) was prepared. The dislocation density of the GaN free-standing substrate was 2×10⁷ cm⁻².

### 2. Etching of Main Surface of Substrate

Referring to FIG. 2(b), the main surface 10m of the GaN free-standing substrate was etched as in EXAMPLE 2.

### 3. Growth of GaN Crystal

Referring to FIG. 2(c), the GaN crystal 20 was grown on the main surface 10m of the GaN free-standing substrate as in EXAMPLE 2. The GaN crystal had a thickness of 5 μm. The main surface of the GaN crystal was measured by an X-ray diffraction method and was found to be a (1-100) surface. The full width at a half maximum of the (1-100) X-ray diffraction peak of the GaN crystal was 520 arcsec and the GaN crystal had high crystallinity. The dislocation density of the GaN crystal was 2×10⁷ cm⁻², which was equal to the dislocation density of the GaN free-standing substrate.

### Example 6

### 1. Preparation of Substrate

Referring to FIG. 2(a), as the substrate 10, a Ga_{0.8}In_{0.2}N template substrate was prepared in which a Ga_{0.8}In_{0.2}N seed crystal (Gaₓ Al_{y} In_{1-x-y} N seed crystal 10a) having a thickness of 3 μm was grown by a MOCVD method on a (0001) main surface of a sapphire substrate (undersubstrate 10b) having a diameter of 2 inches (5.08 cm). Here, the dislocation density of the Ga_{0.8}In_{0.2}N seed crystal of the template substrate was 8×10⁹ cm⁻².

### 2. Etching of Main Surface Of Substrate

Referring to FIG. 2(b), the main surface 10m of the Ga_{0.8}In_{0.2}N template substrate was etched as in EXAMPLE 2.

### 3. Growth of GaN Crystal

Referring to FIG. 2(c), the GaN crystal 20 was grown on the main surface 10m of the Ga_{0.8}In_{0.2}N template substrate as in EXAMPLE 2. The GaN crystal had a thickness of 5 μm. The full width at a half maximum of the (0002) X-ray diffraction peak of the GaN crystal was 540 arcsec. The dislocation density of the GaN crystal was 7×10⁶ cm⁻², which was lower than the dislocation density of the Ga_{0.8}In_{0.2}N template substrate.

### Example 7

### 1. Preparation of Substrate

Referring to FIG. 2(a), as the substrate 10, a Ga_{0.8}Al_{0.2}N template substrate was prepared in which a Ga_{0.8}Al_{0.2}N seed crystal (Gaₓ Al_{y} In_{1-x-y} N seed crystal 10a) having a thickness of 3 μm was grown by a MOCVD method on a (0001) main surface of a sapphire substrate (undersubstrate 10b) having a diameter of 2 inches (5.08 cm). Here, the dislocation density of the Ga_{0.8}Al_{0.2}N seed crystal of the template substrate was 8×10⁹ cm⁻².

### 2. Etching of Main Surface of Substrate

Referring to FIG. 2(b), the main surface 10m of the Ga_{0.8}Al_{0.2}N template substrate was etched as in EXAMPLE 2.

### 3. Growth of GaN Crystal

Referring to FIG. 2(c), the GaN crystal 20 was grown on the main surface 10m of the Ga_{0.8}Al_{0.2}N template substrate as in EXAMPLE 2. The GaN crystal had a thickness of 5 μm. The full width at a half maximum of the (0002) X-ray diffraction peak of the GaN crystal was 420 arcsec. The dislocation density of the GaN crystal was 5×10⁶ cm⁻², which was lower than the dislocation density of the Ga_{0.8}Al_{0.2}N template substrate.

### Example 8

### 1. Preparation of Substrate

Referring to FIG. 2(a), as the substrate 10, a GaN free-standing substrate having a diameter of 2 inches (5.08 cm) was prepared that was cut from a thick GaN crystal grown on a GaAs substrate as described in Japanese Unexamined Patent Application Publication No. 2000-22212. Here, the dislocation density of the GaN free-standing substrate was 5×10⁶ cm⁻². The arithmetical mean deviation Ra (defined in JIS B0601) of the main surface 10m was measured with an atomic force microscope (AFM) and was found to be 100 nm or more. A section of the GaN free-standing substrate was subjected to SEM observation and CL observation and was found that the CL emission intensity of a surface layer ranging from the surface to the depth of 2 μm was weak. This surface layer ranging from the surface to the depth of 2 μm was a work-affected layer formed in the surface layer of the GaN free-standing substrate when the GaN free-standing substrate was cut from the GaN crystal. To remove the work-affected layer, the main surface of the substrate was etched.

### 2. Etching of Main Surface of Substrate

Referring to FIG. 2(b), the main surface 10m of the GaN free-standing substrate was etched as in EXAMPLE 2.

### 3. Growth of GaN Crystal

Referring to FIG. 2(c), the GaN crystal 20 was grown on the main surface 10m of the GaN free-standing substrate as in EXAMPLE 2. The GaN crystal had a thickness of 5 μm. The full width at a half maximum of the (0002) X-ray diffraction peak of the GaN crystal was 420 arcsec. The dislocation density of the GaN crystal was 3×10⁶ cm⁻², which was lower than the dislocation density of the GaN free-standing substrate and was good. The arithmetical mean deviation Ra of the main surface of the GaN crystal was 10 nm or less and no surface layer having a weak CL emission intensity was observed at the interface between the GaN free-standing substrate and the GaN crystal grown on the main surface of the GaN free-standing substrate. That is, the work-affected layer had been removed by the etching of the main surface of the GaN free-standing substrate prior to the growth of the GaN crystal.

### 4. Fabrication of Light Emitting Device

Referring to FIG. 9, a light-emitting diode (LED) serving as a light emitting device was fabricated by forming an LED structure 55 by a MOCVD method on a main surface (of the GaN crystal 20) of a GaN crystal substrate 30 in which the GaN crystal 20 having a thickness of 5 μm was grown on the GaN free-standing substrate (substrate 10). Here, to grow a plurality of group III nitride crystal layers forming the LED structure 55, as group III raw materials, trimethylgallium (TMG), trimethylindium (TMI), and/or trimethylaluminum (TMA) were used; as a nitrogen raw material, ammonia was used; as an n-type dopant material, mono-silane was used; and, as a p-type dopant material, bis(cyclopentadienyl)magnesium (CP₂Mg) was used.

Specifically, on the main surface (of the GaN crystal 20) of the GaN crystal substrate 30, as the plurality of group III nitride crystal layers forming the LED structure 55, an n-type GaN layer 51 having a thickness of 2 μm, a multi-quantum well (MQW) light-emitting layer 52 having a thickness of 88 nm (including seven In_{0.01}Ga_{0.99}N barrier layers 52b having a thickness of 10 nm and six In_{0.14}Ga_{0.86}N well layers 52w having a thickness of 3 nm that were alternately disposed), and a p-type Al_{0.18}Ga_{0.82}N electron-blocking layer 53 having a thickness of 20 nm, and a p-type GaN contact layer 54 having a thickness of 50 nm were sequentially grown by a MOCVD method.

As a p-side electrode 56, a semitransparent ohmic electrode that was constituted by Ni (5 nm)/Au (10 nm) and had a longitudinal width of 400 μm, a lateral width of 400 μm, and a thickness of 15 nm was formed on the p-type GaN contact layer 54 by vacuum deposition. In addition, as an n-side electrode 57, an ohmic electrode that was constituted by Ti (20 nm)/Al (300 nm) and had a longitudinal width of 400 μm, a lateral width of 400 μm, and a thickness of 320 nm was formed on a main surface (of the GaN free-standing substrate (substrate 10)) of the GaN crystal substrate 30 by vacuum deposition. Then, the resultant component was formed into a chip having a longitudinal width of 500 μm and a lateral width of 500 μm to complete the LED.

The thus-provided LED had a light-emitting wavelength of 420 nm and had a light-emitting intensity of 4 mW to 5 mW under the application of a current of 20 mA.

### Reference Example 1

A typical LED was fabricated in the following manner and the light-emitting wavelength and the light-emitting intensity of the LED were measured for comparison with EXAMPLE 8.

### 1. Preparation of Substrate

Referring to FIG. 2(a), as the substrate 10, a GaN free-standing substrate having a diameter of 2 inches (5.08 cm) was prepared that was cut from a thick GaN crystal grown on a GaAs substrate as described in Japanese Unexamined Patent Application Publication No. 2000-22212. Here, the dislocation density of the GaN free-standing substrate was 5×10⁶ cm⁻². The arithmetical mean deviation Ra (defined in JIS B0601) of the main surface 10m was measured with an atomic force microscope (AFM) and was found to be 100 nm or more. A section of the GaN free-standing substrate was subjected to SEM observation and CL observation and was found that the CL emission intensity of a surface layer ranging from the surface to the depth of 2 μm was weak. This surface layer ranging from the surface to the depth of 2 μm was a work-affected layer formed in the surface layer of the GaN free-standing substrate when the GaN free-standing substrate was cut from the GaN crystal. To remove the work-affected layer, the main surface of the substrate was polished.

### 2. Polishing of Main Surface of Substrate

The main surface 10m of the GaN free-standing substrate (substrate 10) was polished with diamond abrasives having an average particle diameter of 0.1 μm and then further finely polished with colloidal silica abrasives having an average particle diameter of 0.02 μm. The arithmetical mean deviation Ra of the polished main surface of the GaN free-standing substrate was 10 nm or less and no surface layer having a weak CL emission intensity was observed. That is, the work-affected layer had been removed by the polishing of the main surface of the GaN free-standing substrate.

### 3. Fabrication of Light Emitting Device

Referring to FIG. 10, as in EXAMPLE 8, on a main surface of the GaN free-standing substrate (substrate 10), as the plurality of group III nitride crystal layers forming the LED structure 55, the n-type GaN layer 51 having a thickness of 2 μm, the multi-quantum well (MQW) light-emitting layer 52 having a thickness of 88 nm (including seven In_{0.01}Ga_{0.99}N barrier layers 52b having a thickness of 10 nm and six In_{0.14}Ga_{0.86}N well layers 52w having a thickness of 3 nm that were alternately disposed), and the p-type Al_{0.18}Ga_{0.82}N electron-blocking layer 53 having a thickness of 20 nm, and the p-type GaN contact layer 54 having a thickness of 50 nm were sequentially grown by a MOCVD method. Furthermore, as the p-side electrode 56, a semitransparent ohmic electrode that was constituted by Ni (5 nm)/Au (10 nm) and had a longitudinal width of 400 μm, a lateral width of 400 μm, and a thickness of 15 nm was formed on the p-type GaN contact layer 54 by vacuum deposition. In addition, as the n-side electrode 57, an ohmic electrode that was constituted by Ti (20 nm)/Al (300 nm) and had a longitudinal width of 400 μm, a lateral width of 400 μm, and a thickness of 320 nm was formed on another main surface of the GaN free-standing substrate (substrate 10) by vacuum deposition. Then, the resultant component was formed into a chip having a longitudinal width of 500 μm and a lateral width of 500 μm to complete the LED.

The thus-provided LED had a light-emitting wavelength of 420 nm and had a light-emitting intensity of 4 mW to 5 mW under the application of a current of 20 mA. Thus, the LED had characteristics equivalent to the LED in EXAMPLE 8.

Comparison between EXAMPLE 8 and REFERENCE EXAMPLE 1 clearly shows that, in the fabrication of a light emitting device, even when the removal of a work-affected layer in a main surface of a substrate is performed by etching of the main surface of the substrate and crystal growth instead of polishing of the main surface of the substrate, a light emitting device having a light-emitting wavelength and a light-emitting intensity that are equivalent to those provided by the polishing can be provided. That is, in the production of a light emitting device, as a result of performing the removal of a work-affected layer in a main surface of a substrate by etching of the main surface of the substrate and crystal growth, the costly step of polishing the main surface of the substrate can be omitted.

### Example 9

### 1. Preparation of Substrates

Referring to FIG. 2(a), 1110 GaN template substrates (substrates 10) that were the same as that in EXAMPLE 1 were prepared. Referring to FIG. 5, one of the GaN template substrates (substrates 10) and 85 g of metal Ga having a purity of 99.9999 mass % were placed in a carbon crucible A (crystal growth vessel 1A) having an inner diameter of 6 cm and a height of 5 cm; and such 37 crucibles A (crystal growth vessels 1A) each containing the metal Ga and the single GaN template substrate were prepared. Referring to FIG. 6, in a carbon crucible B (crystal growth vessel 1B) having an inner diameter of 45 cm and a height of 5 cm, the above-described 37 GaN template substrates (substrates 10) were two-dimensionally arranged so as to be hexagonal close-packed as illustrated in FIGS. 6, and 470 g of metal Ga having a purity of 99.9999 mass % were also placed; and such 29 crucibles B (crystal growth vessels 1B) each containing the metal Ga and the 37 GaN template substrates were prepared.

Then, referring to FIG. 8, the 29 crucibles B (crystal growth vessels 1B) each containing metal Ga and 37 GaN template substrates were arranged in the vertical direction (that is, the crucibles B were stacked in 29 levels) in the crystal growth chamber 110. A flat plate 130 composed of carbon was placed above the crucible B at the uppermost level. As illustrated in FIG. 7, the 37 crucibles A (crystal growth vessels 1A) each containing metal Ga and a single GaN template substrate were two-dimensionally arranged in the horizontal direction so as to be hexagonal close-packed on the flat plate 130. Thus, the 29 crucibles B constituting the 29 levels and the 17 crucibles A constituting the single level were arranged in the crystal growth chamber 110.

### 2. Etching of Main Surfaces of Substrates

Then, a nitrogen gas having a purity of 99.999 mass % was supplied into the crystal growth chamber 110. The crucibles A and the crucibles B were maintained at 30 atmospheres (3.04 MPa) and heated from room temperature (25° C.) to 1100° C. in 3 hours. At this time, the metal Ga placed in the crucibles A and the crucibles B was molten into the Ga melts 3 and the solutions 7 provided by the dissolution 5 of nitrogen in the Ga melts 3 were in contact with the main surfaces 10m of the substrates 10. However, under such a condition, since the amount of nitrogen dissolved in the Ga melts was small, GaN crystals were not grown and the main surfaces 10m of the GaN seed crystals of the GaN template substrates were etched.

### 3. Growth of GaN Crystals

Then, referring to FIG. 8, a nitrogen gas having a purity of 99.999 mass % was supplied into the crystal growth chamber 110. The crucibles A (crystal growth vessels 1A) and the crucibles B (crystal growth vessels 1B) were maintained at 1100° C. and pressurized from 30 atmospheres (3.04 MPa) to 1950 atmospheres (197.5 MPa) in 2 hours. Then, the crucibles A and the crucibles B were maintained in the nitrogen atmosphere at 1950 atmospheres and at 1100° C. for 10 hours.

At this time, the amount of nitrogen dissolved in the Ga melts that were in contact with the main surfaces 10m of the GaN template substrates (substrates 10) was increased and GaN crystals were grown on the main surfaces 10m of the GaN seed crystals 10a of all the 1110 GaN template substrates. Among the 1110 grown GaN crystals, the thickest GaN crystal had a thickness of 7 μm and the thinnest GaN crystal had a thickness of 2 μm. As for the full width at a half maximum of the (0002) X-ray diffraction peaks of 30 GaN crystals drawn from the 1110 GaN crystals, the maximum was 470 arcsec and the minimum was 280 arcsec. Thus, the GaN crystals had high crystallinity. As for the dislocation density of the 30 GaN crystals, the maximum was 8×10⁶ cm⁻² and the minimum was 3×10⁶ cm⁻². Thus, the dislocation density was lower than the dislocation density of the GaN seed crystals of the substrates and the GaN crystal in EXAMPLE 1.

Compared with EXAMPLE 1, every GaN crystal drawn in EXAMPLE 9 had a low full width at a half maximum of the X-ray diffraction peak and a low dislocation density, that is, a low dislocation density and high crystallinity. This is probably because, as a result of the etching of the main surfaces of the substrates, work-affected layers and/or surface oxidized layers in the main surfaces of the substrates and/or stains adhering to the main surfaces of the substrates were removed and good crystal growth was performed.

The embodiments and EXAMPLES that are disclosed herein should be understood as examples in all the respects and not being imitative. The scope of the present invention is indicated by not the descriptions above but the Claims and is intended to embrace all the modifications within the meaning and range of equivalency of the Claims.

### REFERENCE SIGNS LIST

1, 1A, 1B crystal growth vessel
3 Ga melt
5 dissolution of nitrogen in Ga melt
7 solution
10 substrate
10a Gaₓ Al_{y} In_{1-x-y} N seed crystal
10b undersubstrate
10e surface layer removed by etching
10h, 20h crystal region with inverted polarity
10k, 20k main crystal region
10m, 10hm, 10km main surface
10v, 10w pit
20 GaN crystal
20c bonding crystal region
30 GaN crystal substrate
51 n-type GaN layer
52 MQW light-emitting layer
52b In_{0.01}Ga_{0.99}N barrier layer
52w In_{0.14}Ga_{0.86}N well layer
53 p-type Al_{0.18}Ga_{0.82}N electron-blocking layer
54 p-type GaN contact layer
55 LED structure
56 p-side electrode
57 n-side electrode
110 crystal growth chamber
110e gas supply port
120 heater
130 flat plate

1. A method for growing a GaN crystal comprising:
a step of preparing a substrate (10) that includes a main surface (10m) and includes a Gaₓ Al_{y} In_{1-x-y} N (0<x, 0≦y, and x+y≦1) seed crystal (10a) including the main surface (10m), and
a step of growing a GaN crystal (20) on the main surface (10m) at an atmosphere temperature of 800° C. or more and 1500° C. or less and at an atmosphere pressure of 500 atmospheres or more and less than 2000 atmospheres by bringing a solution (7) provided by dissolving nitrogen in a Ga melt (3) into contact with the main surface (10m) of the substrate (10).

2. The method for growing a GaN crystal according to claim 1 further comprising, after the step of preparing the substrate (10) and before the step of growing the GaN crystal (20), a step of etching the main surface (10m) of the substrate (10).

3. The method for growing a GaN crystal according to claim 2, wherein the step of etching the main surface (10m) of the substrate (10) is performed by bringing the solution (7) provided by dissolving nitrogen in the Ga melt (3) into contact with the main surface (10m) of the substrate (10) at an atmosphere temperature of 800° C. or more and 1500° C. or less and at an atmosphere pressure of 1 atmosphere or more and less than 500 atmospheres.

4. The method for growing a GaN crystal according to claim 1, wherein the Gaₓ Al_{y} In_{1-x-y} N seed crystal (10a) of the substrate (10) includes a main crystal region (10k) and a crystal region (10h) with an inverted polarity in which a polarity in a [0001] direction is inverted with respect to the main crystal region (10k).

5. The method for growing a GaN crystal according to claim 4, wherein, in the substrate (10), a main surface (10hm) of the crystal region (10h) with the inverted polarity is recessed at a depth of 10 μm or more with respect to a main surface (10km) of the main crystal region (10k).

6. The method for growing a GaN crystal according to claim 1, wherein, in the step of preparing the substrate (10), a plurality of the substrates (10) are prepared, a plurality of crystal growth vessels (1, 1A, and 1B) each containing one or more of the substrates (10) are prepared, and the plurality of crystal growth vessels (1, 1A, and 1B) are arranged in at least one of a horizontal direction and a vertical direction in a crystal growth chamber (110).
